(19) United States
(12) Patent Application Publication
(10) Pub. No.: US 2011/0083885 A1
(43) Pub. Date: Apr. 14, 2011

(54) METAL WIRING STRUCTURE COMPRISING ELECTROLESS NICKEL PLATING LAYER AND METHOD OF FABRICATING THE SAME

(76) Inventors: Tae Hyun KIM, Seoul (KR); Seog Moon Choi, Seoul (KR); Tae Hoon Kim, Gyunggi-do (KR); Sang Hyun Shin, Gyunggi-do (KR); Young Ki Lee, Gyunggi-do (KR); Sung Keun Park, Gyunggi-do (KR)

(21) Appl. No.: 12/630,478

(22) Filed: Dec. 3, 2009

(30) Foreign Application Priority Data
Oct. 8, 2009 (KR) 10-2009-0095753

(51) Int. Cl. H05K 1/09; B05D 5/12

(52) U.S. Cl. 174/257; 427/97.1

(57) ABSTRACT

Disclosed herein is a metal wiring structure, including: an electroless nickel plating layer formed on an insulation layer; and a surface treatment layer formed on the electroless nickel plating layer, and a method of fabricating the same. The metal wiring structure has excellent adhesivity without regard to the kind of substrate and can be easily fabricated.

### CROSS REFERENCE TO RELATED APPLICATION

This application claims the benefit of Korean Patent Application No. 10-2009-0095753, filed Oct. 8, 2009, entitled “A Metal Layer Structure Comprising Electroless Ni Plating Layer and A Fabricating Method The Same”, which is hereby incorporated by reference in its entirety into this application.

### BACKGROUND OF THE INVENTION

1. Technical Field

The present invention relates to a metal wiring structure comprising an electroless nickel plating layer and a method of fabricating the same.

2. Description of the Related Art

Recently, in the field of electromagnetic wiring substrates and wafer level chip size packages (WLSCPs), metal wiring has been rapidly miniaturized because of the densification of metal wiring, and thus its width and length has become remarkably narrowed. For this reason, metal wiring and metal bumps are formed by a semi-additive process.

In the semi-additive process, a seed layer is physically formed on an insulation layer, and then a resist pattern for forming wiring or bump is formed on the seed layer using photolithography. Subsequently, electrolytic copper plating or solder plating is conducted, a resist is separated, and then the seed layer, which becomes unnecessary, is etched and thus removed.

Meanwhile, a seed layer, serving as an adhesion layer for forming an electroless copper plating layer or a solder plating layer on an insulation layer, is formed in various shapes and ways depending on the kind of substrate. For example, in printed circuit boards (PCBs), a seed layer is formed using electroless copper plating, and, in ceramic substrates, such as low temperature co-fired ceramic (LTCC) substrates and high temperature co-fired ceramic (HTCC) substrates, a seed layer is formed by calcinating tungsten (W) or molybdenum (Mo) powder or by sputtering titanium (Ti), tungsten (W) or chromium (Cr). Further, in silicon substrates, such as wafers and the like, a seed layer is to formed by sputtering titanium (Ti), titanium-tungsten (TiW), nickel-chromium (NiCr) or chromium (Cr).

However, these conventional seed layer structures and methods of forming the same are problematic as follows.

First, an electroless copper plating layer exhibits sufficient adhesivity on printed circuit boards (PCBs), but does not exhibit sufficient adhesivity on ceramic substrates and silicon substrates.

Further, a tungsten (W) or molybdenum (Mo) layer formed by a calcination process has high reliability even at high temperature, but has problems in that a long-term curing process is required to be performed at a high temperature of 600° C. or more in order to calcinate tungsten (W) or molybdenum (Mo), process time increases, and process costs are high. Moreover, there is a problem in that it is difficult to apply the tungsten (W) or molybdenum (Mo) layer to a substrate which is vulnerable to damage upon the application of stress attributable to temperature or to a substrate which is not resistant to high temperature.

Furthermore, the method of forming a seed layer by sputtering titanium (Ti), titanium-tungsten (TiW), nickel-chromium (NiCr) or chromium (Cr) is generally used because the seed layer is densely formed on an insulation layer in a particulate shape, but is problematic in that it is difficult to form a thick film due to the limitations of sputtering, and thus a process of forming a plating layer is additionally required. For example, when a plating process, which is a wet process, is performed after a sputtering process, which is a dry process, there are problems in that process time and cost greatly increase, and stress seriously occurs between a film formed by a dry process and a film formed by a wet process.

### SUMMARY OF THE INVENTION

Accordingly, the present invention has been made to solve the above-mentioned problems, and the present invention provides a metal wiring structure including an electroless nickel plating layer in which a seed layer has adhesivity without regard to the kind of a substrate and which can be easily fabricated, and a method of fabricating the same.

An aspect of the present invention provides a metal wiring structure, including: an electroless nickel plating layer formed on an insulation layer; and a surface treatment layer formed on the electroless nickel plating layer.

Here, the insulation layer may be selected from among an anode oxide layer, a ceramic resin layer, an epoxy resin layer, and a silicon resin layer.

Further, the electroless nickel plating layer may include an electrolytic copper plating layer formed thereon.

Further, the surface treatment layer may be one or more selected from among a gold plating layer, an electroless silver plating layer, an electroless tin plating layer, and a preflux coating layer.

Further, the metal wiring may be an under bump metal (UBM) film.

Another aspect of the present invention provides a method of fabricating a metal wiring including an electroless nickel plating layer, including: forming a reactive group on an insulation layer; adsorbing catalyst particles on the insulation layer to activate the insulation layer; reducing nickel ions and then depositing the reduced nickel ions on the insulation layer to form an electroless nickel plating layer; and forming a surface treatment layer on the electroless nickel plating layer.

Here, the method of fabricating a metal wiring may further include, before the forming of the reactive group: removing organic and inorganic pollutants from the insulation layer to clean the insulation layer; and removing scales from the insulation layer to acid-pickle the insulation layer.

Further, the method of fabricating a metal wiring may further include, between the forming of the electroless nickel plating layer and the forming of the surface treatment layer, forming a copper plating layer on the electroless nickel plating layer.

Further, in the forming of the surface treatment layer, the surface treatment layer may be one or more selected from among a gold plating layer, an electroless silver plating layer, an electroless tin plating layer, and a preflux coating layer.

Further, the metal wiring may be an under bump metal (UBM) film.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B are sectional views showing metal wiring structures including an electroless nickel plating layer according to a first embodiment of the present invention;

FIGS. 2A and 2B are sectional views showing metal wiring structures including an to electroless nickel plating layer according to a second embodiment of the present invention; and

FIG. 3 is a flowchart showing a process of fabricating a metal wiring structure including an electroless nickel plating layer according to a preferred embodiment of the present invention.

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

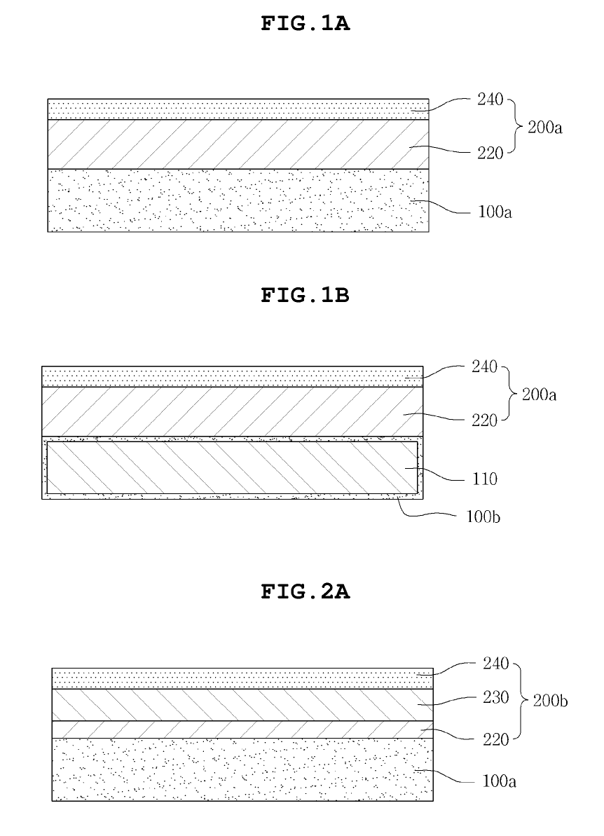

FIGS. 1A and 1B are sectional views showing metal wiring structures including an electroless nickel plating layer according to a first embodiment of the present invention. Hereinafter, metal wiring structures including an electroless nickel plating layer according to the first embodiment will be described with reference to FIGS. 1A and 1B.

As shown in FIGS. 1A and 1B, a metal wiring 200a according to this embodiment has a structure in which a surface treatment layer 240 is formed on an electroless nickel plating layer 220. That is, this embodiment is characterized in that the metal wiring 200a has a single layer structure of the electroless nickel plating layer 220 except for the surface treatment layer 240. Like this, when a metal wiring has a single layer structure, the reliability degradation attributable to stress and heat occurring at the interlayer interfaces of a multilayer structure can be prevented. However, when the metal wiring 200a is formed of the electroless nickel plating layer 220, since the electroless nickel plating layer 220 has high electric resistance, it is preferred that the metal wiring structure of this embodiment be used as a metal wiring structure which is not influenced by high electric resistance.

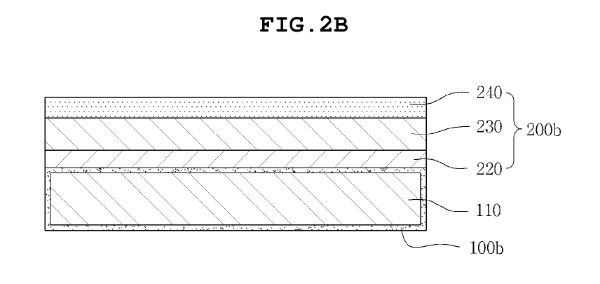

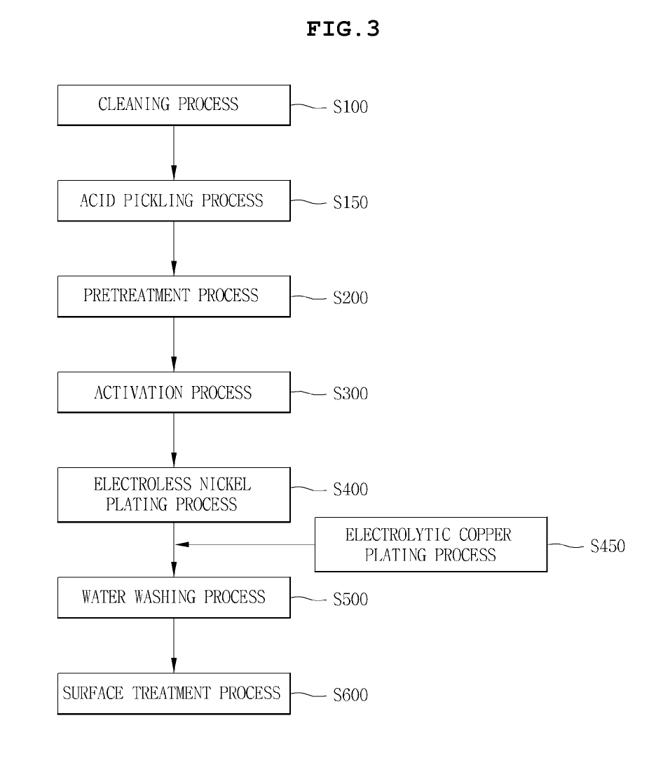

The electroless nickel plating layer 220 is formed on an insulation layer 100a (refer to FIG. 1A) or an anode oxide layer 100b (refer to FIG. 2B) applied on the surface of a metal plate 110 by an electroless nickel plating process (refer to FIG. 3). Here, since the electroless nickel plating layer 220 has excellent adhesivity regardless of the kind of material, it is formed on the anode oxide layer 100b as well as the resin insulation layer 100a such as a ceramic resin layer, an epoxy resin layer, a silicon resin layer or the like.

The surface treatment layer 240, which serves to prevent the oxidization of the metal wiring 200a and allow a solder bump to be easily formed, is formed on the electroless nickel plating layer 220. For example, the surface treatment layer 240 may be one or more selected from among a gold plating layer, an electroless silver plating layer, an electroless tin plating layer and a preflux (organic solderability preservative: OSP) coating layer.

The metal wiring 200a having such a structure has solder wettability so that a solder bump as well as a wiring layer of a circuit can be easily adhered thereto, and can be used as an under bump metal (UBM) film for preventing the diffusion of solder components.

FIGS. 2A and 2B are sectional views showing metal wiring structures including an electroless nickel plating layer according to a second embodiment of the present invention. Hereinafter, metal wiring structures including an electroless nickel plating layer according to the second embodiment will be described with reference to FIGS. 2A and 2B. Redundant descriptions in the description of the second embodiment of the present invention, compared to the description of the aforementioned first embodiment, will be omitted.

As shown in FIGS. 2A and 2B, a metal wiring 200b according to this embodiment has a structure in which an electrolytic copper plating layer 230 is formed on an electroless nickel plating layer 220 and a surface treatment layer 240 is formed on the electrolytic copper plating layer 230. That is, this embodiment is characterized in that the metal wiring 200b has a multi-layer structure of the electroless nickel plating layer 220 and the electrolytic copper layer 230. In this embodiment, the electrolytic copper plating layer 230 serves to make up for the low electrical characteristics of the electroless nickel plating layer 220.

Here, the electrolytic copper plating layer 230, which uses the conductivity of the electroless nickel plating layer 220, is formed by applying a cathode to a substrate and applying an anode to an anode ball serving as a supply source of copper and thus causing an oxidation reaction in which copper ions are produced from a plating solution and the anode ball and a reduction reaction in which the copper ions are plated (deposited) on the substrate.

FIG. 3 is a flowchart showing a process of fabricating a metal wiring structure including an electroless nickel plating layer according to a preferred embodiment of the present invention. As shown in FIG. 3, a metal wiring structure including an electroless nickel plating layer according to a preferred embodiment of the present invention is formed by the processes of pretreatment (S200)→activation (S300)→electroless nickel plating (S400)→surface treatment (S600). Hereinafter, the process of fabricating a metal wiring structure will be described by the respective processes.

The pretreatment process (S200) is a process of forming a reactive group on an insulation layer 100a using an organic material in order to easily form an active layer on an anode oxide layer 100b. In a conventional electroless plating process, this pretreatment process is not performed, so that an electroless nickel plating layer 220 is not easily formed on the insulation layer 100a, and, even if the electroless nickel plating layer 220 is formed, the adhesion between the insulation layer 100a and the electroless nickel plating layer 220 is not sufficient. However, in the present invention, since the pretreatment process (S200) for forming a reactive group on the insulation layer 100a using an organic material is performed, the active layer can be more easily formed, and the adhesion between the insulation layer 100a and the electroless nickel plating layer 220 becomes sufficient.

Prior to this pretreatment process (S200), a cleaning process (S100) of removing organic and inorganic pollutants from the surface of the insulation layer 100a and an acid pickling process (S150) of removing scales may be selectively performed. Through the cleaning process (S100) and the acid pickling process (S150), the wettability of the insulation layer 100a is improved, and thus the adsorptivity of catalyst particles onto the insulation layer can be increased.

The activation process is a process for forming an active layer. In this activation process, catalyst particles, such as palladium (Pd) particles, are adsorbed on the insulation layer 100, and are then forcibly ionic-activated into palladium ions to form an active layer. In this case, since the insulation layer 100a, particularly, an anode oxide layer 100b, is formed thereon with an organic reactive group through the pretreatment process, the active layer can be more easily formed.

The electroless nickel plating process (S400) is a process of depositing a nickel plating layer on the insulation layer 100a. For example, the electroless nickel plating process (S400) is performed by immersing the insulation layer 100a into a nickel plating solution containing nickel sulfate. In this case, palladium ions are substituted with nickel ions, and thus nickel metal is deposited on the insulation layer 100a.

The surface treatment process (S600) is a process of forming one or more surface treatment layers selected from among a gold plating layer, an electroless silver plating layer, an electroless tin plating layer and a preflux (organic solderability preservative: OSP) coating layer. The surface treatment process (S600) is performed in order to prevent the oxidization of the electroless nickel plating layer 220 or the electrolytic copper plating layer 230 and to improve solder wettability (solderability).

Here, a gold plating layer is frequently used because it does not discolor for a long period of time and it has excellent conductivity and corrosion resistance and low contact resistance. The gold plating layer is formed by an electrolytic soft gold plating process, an electrolytic hard gold plating process or an electroless gold plating process using a substitutional plating solution or a reductional plating solution.

An electroless silver plating layer is frequently used because it has excellent heat resistance and solderability and it is prepared in a low working temperature to prevent the warpage of a substrate. The electroless silver plating layer is formed by an electroless plating process.

An electroless tin plating layer is frequently used because it has excellent solderability and low corrosivity and it is easily available.

A preflux (organic solderability preservative: OSP) coating layer is frequently used because it has more excellent soldering properties than other surface treatment layers, and is formed by applying a resin using roll coating, spraying or the like.

Meanwhile, prior to the surface treatment process (S600), an electrolytic copper plating process (S450) for forming an electrolytic copper plating layer on the electroless nickel plating layer 220, and a water washing process (S500) for removing residues from the surface of the electroless nickel plating layer 220 or the electrolytic copper plating layer 230 may be performed. The electrolytic copper plating process (S450) is performed using a commonly-used method, and the water washing process (S500) is formed by spraying nonionic water or ultrapure water.

As described above, the present invention provides a metal wiring structure which has excellent adhesivity without regard to the kind of a substrate because an electroless nickel plating layer is used as a seed layer and which can be easily fabricated, and a method of fabricating the same.

According to the metal wire structure of the present invention, since an electroless nickel plating layer, like an electrolytic copper plating layer, is formed by a wet process, stress occurring at the interface can be minimized compared to conventional metal wiring structures fabricated by a wet sputtering process. Further, since both dry type equipment and wet type equipment are not required, a manufacturing process is simplified, production costs are decreased, and the defective fraction of products is reduced.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A metal wiring structure, comprising:
an electroless nickel plating layer formed on an insulation layer; and
a surface treatment layer formed on the electroless nickel plating layer.

2. The metal wiring structure according to claim 1, wherein the insulation layer is selected from among an anode oxide layer, a ceramic resin layer, an epoxy resin layer, and a silicon resin layer.

3. The metal wiring structure according to claim 1, wherein the electroless nickel plating layer includes an electrolytic copper plating layer formed thereon.

4. The metal wiring structure according to claim 1, wherein the surface treatment layer is one or more selected from among a gold plating layer, an electroless silver plating layer, an electroless tin plating layer, and a preflux coating layer.

5. The metal wiring structure according to claim 1, wherein the metal wiring is an under bump metal (UBM) film.

6. A method of fabricating a metal wiring including an electroless nickel plating layer, comprising:
forming a reactive group on an insulation layer;
adsorbing catalyst particles on the insulation layer to activate the insulation layer;
reducing nickel ions and then depositing the reduced nickel ions on the insulation layer to form an electroless nickel plating layer; and
forming a surface treatment layer on the electroless nickel plating layer.

7. The method of fabricating a metal wiring according to claim 6, further comprising, before the forming of the reactive group:
removing organic and inorganic pollutants from the insulation layer to clean the insulation layer; and
removing scales from the insulation layer to acid-pickle the insulation layer.

8. The method of fabricating a metal wiring according to claim 6, further comprising, between the forming of the electroless nickel plating layer and the forming of the surface treatment layer:
forming a copper plating layer on the electroless nickel plating layer.

9. The method of fabricating a metal wiring according to claim 6, wherein, in the forming of the surface treatment layer, the surface treatment layer is one or more selected from among a gold plating layer, an electroless silver plating layer, an electroless tin plating layer, and a preflux coating layer.

10. The method of fabricating a metal wiring according to claim 6, wherein the metal wiring is an under bump metal (UBM) film.
